(19) United States
(12) Patent Application Publication
(10) Pub. No.: US 2025/0311164 A1
(43) Pub. Date: Oct. 2, 2025

(54) ELECTRONIC DEVICE

(71) Applicant: Panasonic Automotive Systems Co., Ltd., Kanagawa (JP)

(72) Inventors: Ryusuke NABESHIMA, Kanagawa (JP); Yuki IIDA, Kanagawa (JP)

(21) Appl. No.: 19/089,866

(22) Filed: Mar. 25, 2025

(30) Foreign Application Priority Data
Mar. 28, 2024 (JP) 2024-052923

(51) Int. Cl. H05K 7/20

(52) U.S. Cl. CPC H05K 7/2039

(57) ABSTRACT

An electronic device Includes: a circuit board on which an electronic component that generates heat is mounted; a heat sink that covers the electronic component and is in contact with the electronic component; and a standing wall that surrounds the electronic component and is Interposed between the heat sink and the circuit board.

### CROSS REFERENCE TO RELATED APPLICATION

The present application is based on and claims priority of Japanese Patent Application No. 2024-052923 filed on Mar. 28, 2024.

### FIELD

The present disclosure relates to an electronic device.

### BACKGROUND

Conventionally, in conjunction with the expanding multi-functionality and increasing performance of electronic devices, there is also an expected increase in power consumption as the electronic components provided in such electronic devices shift toward high-performance and high-speed applications. For this reason, there is a demand for enhancing heat-dissipation performance in response to demands related to electromagnetic compatibility (EMC) and increases in the amount of heat emitted by electronic components.

For example, Patent Literature (PTL) 1 discloses an electronic device that includes a lid that is disposed on a printed substrate so as to stay in close contact with electronic components via a heat-dissipating gel while covering electronic components that act as a source of noise.

### CITATION LIST

### Patent Literature

PTL 1: Japanese Unexamined Patent Application Publication No. 2021-64670

### SUMMARY

The electronic device according to PTL 1 can be improved upon.

In view of this, the present disclosure is capable of further improving upon the related art.

An electronic device according to one aspect of the present disclosure includes: a circuit board on which an electronic component that generates heat is mounted; a heat sink that covers the electronic component and is in contact with the electronic component; and a standing wall that surrounds the electronic component and is interposed between the heat sink and the circuit board.

The electronic device according to one aspect of the present disclosure is capable of further improving upon the related art.

### BRIEF DESCRIPTION OF DRAWINGS

These and other advantages and features of the present disclosure will become apparent from the following description thereof taken in conjunction with the accompanying drawings that illustrate a specific embodiment of the present disclosure.

FIG. 1 is a cross-sectional view of an electronic device according to an embodiment.

FIG. 2A is a cross-sectional view of an electronic device according to a comparative example.

FIG. 2B is a drawing that illustrates noise levels and frequencies of an electronic component.

FIG. 3 is a cross-sectional view of an electronic device in which a heat sink and standing walls are provided as separate units.

FIG. 4 is a cross-sectional view of an electronic device that includes a first substrate and a second substrate.

FIG. 5 is a cross-sectional view of an electronic device that includes first standing walls and second standing walls.

### DESCRIPTION OF EMBODIMENT

Hereinafter, an exemplary embodiment will be specifically described with reference to the drawings.

It should be noted that the embodiment described below merely illustrates general or specific examples of the present disclosure. The numerical values, shapes, materials, elements, arrangement, positions, and connection states of the elements, etc., described in the following embodiment are mere examples, and are therefore not intended to limit the present disclosure. Accordingly, among elements in the following embodiment, those not appearing in any of the independent claims will be described as optional elements.

It should be noted that the figures are schematic diagrams and are not necessarily precise illustrations. In the figures, substantially same elements are given the same reference numbers. It should be noted that, even in a case where content illustrated in the figures is not described in detail in an embodiment, the content is considered to be included in the embodiment disclosed.

In the following embodiment, expressions such as “rectangularly board-shaped” and the like are used. For example, “rectangularly board-shaped” not only refers to rectangular board shapes, but also includes substantially rectangular board shapes, i.e., including an error of approximately several percent. In addition, “rectangularly board-shaped” means rectangularly board-shaped to an extent that the advantageous effects of the present disclosure can be achieved. The same applies to other expressions using “shaped”.

### EMBODIMENT

### <Configuration>

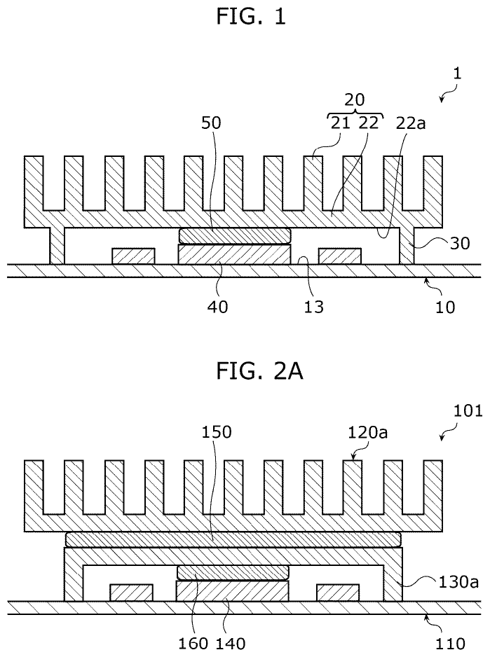

Hereinafter, electronic device 1 according to an embodiment will be described with reference to FIG. 1.

FIG. 1 is a cross-sectional view of electronic device 1 according to an embodiment.

As illustrated in FIG. 1, electronic device 1 is, for example, an electronic device 1 for in-vehicle use provided in a vehicle or an electronic device 1 provided in an information processing device, such as a computer or the like.

Electronic device 1 includes electronic component 40, circuit board 10, heat sink 20, standing walls 30, and heat-dissipating component 50.

Circuit board 10 is a printed substrate in which patterns of metal wiring that include copper foil or the like are provided. A plurality of electronic components 40 that generate heat are mounted on surface 13 of circuit board 10 according to the present embodiment. Electronic component 40 is a semiconductor element that is electrically connected to the metal wiring of circuit board 10. Electronic component 40 is a semiconductor element (integrated circuit), and is at least one of a system on a chip (SoC), a power supply integrated circuit (IC), or a memory element, for example.

In the metal wiring disposed in surface 13 of circuit board 10, first lands (not illustrated in the figures) for connection to establish a solder joint with electronic component 40 and second lands (not illustrated in the figures) for grounding to establish a connection between standing walls 30 and ground are provided.

A first land is disposed so as to be overlapped by electronic component 40. The first land is electrically connected to electronic component 40 via solder (not illustrated in the figures).

A second land is disposed so as to be overlapped by standing wall 30. The second land is electrically connected to standing wall 30 via solder. Since standing wall 30 is connected by solder to the second land, standing wall 30 is both physically connected to circuit board 10 and connected to ground.

In the present embodiment, circuit board 10 is rectangularly board-shaped, for example. It should be noted that the shape of circuit board 10 is not limited to this example, and may be circular in shape or another polygonal shape.

Heat sink 20 is a heat-dissipating element for dissipating heat from electronic component 40. Heat sink 20 is made of a metal material, such as aluminum, copper, or the like, for example.

Heat sink 20 covers electronic component 40 and is in contact with electronic component 40. In the present embodiment, heat sink 20 is in contact with electronic component 40 via heat-dissipating component 50. In this manner, since heat sink 20 and electronic component 40 are in thermal connection with each other, the heat from electronic component 40 can be dissipated.

Heat sink 20 includes a board-shaped base portion 22 and a plurality of fins 21.

Base portion 22 is board shaped. Base portion 22 covers electronic component 40 and is supported by standing walls 30.

Base portion 22 is directly or indirectly in contact with electronic component 40. In the present embodiment, base portion 22 is thermally connected to at least one electronic component 40 of electronic components 40 via heat-dissipating component 50. Accordingly, base portion 22 is indirectly connected to electronic component 40.

The plurality of fins 21 protrude toward a direction opposite of circuit board 10 from a surface of base portion 22 facing away from circuit board 10.

Standing walls 30 are provided as a single unit with heat sink 20. Standing walls 30 “being provided as a single unit” with heat sink 20 means that standing walls 30 and heat sink 20 cannot be separated from each other without damaging standing walls 30 or heat sink 20.

Standing walls 30 surround electronic component 40 and form a frame shape that houses electronic component 40 therein. Standing walls 30 extend toward circuit board 10 from base portion 22, and one end of standing wall 30 may be connected by solder to a second land of circuit board 10. Furthermore, standing walls 30 may be connected to circuit board 10 by fixing components, such as screws, bolts, or the like.

Accordingly, standing walls 30 are interposed between heat sink 20 and circuit board 10. In other words, standing walls 30 and heat sink 20 cover the surroundings of electronic component 40 so as to house electronic component 40. Accordingly, even when noise is generated by electronic component 40, heat sink 20 and standing walls 30 can prevent such noise from being emitted from electronic device 1.

Heat-dissipating component 50 is interposed between electronic component 40 and heat sink 20. In other words, heat-dissipating component 50 thermally connects electronic component 40 and base portion 22 of heat sink 20. Accordingly, when electronic component 40 generates heat, heat-dissipating component 50 can transfer heat from electronic component 40 to base portion 22. Heat-dissipating component 50 is at least one of a heat-dissipating grease, heat-dissipating gel, heat-dissipating polymer, or the like.

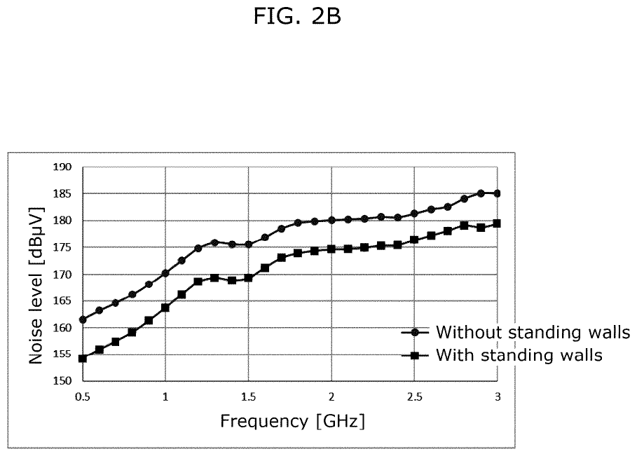

Here, the heat-dissipation performance of electronic device 101 of a comparative example and the heat-dissipation performance of electronic device 1 according to the present embodiment will be described with reference to FIG. 2A. FIG. 2A is a cross-sectional view of electronic device 101 according to a comparative example.

For example, electronic device 101 according to the comparative example includes electronic component 140, circuit board 110 on which electronic component 140 is mounted, shield 130a that covers electronic component 140 so as to house electronic component 140, first heat-dissipating material 160 that thermally connects shield 130a and electronic component 140, heat sink 120a, and second heat-dissipating material 150 that is interposed between heat sink 120a and shield 130a and thermally connects heat sink 120a and shield 130a.

In this case, for example, when electronic component 140 is 25 mm×25 mm in size, the area of first heat-dissipating material 160 and second heat-dissipating material 150 is 25 mm×25 mm, the thickness of first heat-dissipating material 160 and second heat-dissipating material 150 is 1 mm, the thermal conductivity of first heat-dissipating material 160 and second heat-dissipating material 150 is 10 W/(m·K), and thermal contact resistance is 0.2 K/W, thermal resistance R1 between electronic component 140 and shield 130a via first heat-dissipating material 160 is 0.36 K/W. Furthermore, when shield 130a is 65 mm×65 mm in size, the thickness of shield 130a is 2 mm, and the thermal conductivity of shield 130a is 96 W/(m·K), thermal resistance R2 between first heat-dissipating material 160 and second heat-dissipating material 150 via shield 130a is 0.004931 K/W. Furthermore, when second heat-dissipating material 150 is 65 mm×65 mm in size, the thickness of second heat-dissipating material 150 is 1 mm, the thermal conductivity of second heat-dissipating material 150 is 10 W/(m·K), and thermal contact resistance is 0.2 K/W, thermal resistance R3 between shield 130a and heat sink 120a via second heat-dissipating material 150 is 0.223669 K/W.

In electronic device 101 of the comparative example, thermal resistance R between a top surface of electronic component 140 and a surface of a base portion in heat sink 120a facing circuit board 110 is R1+R2+R3=0.5886 K/W.

On the other hand, in electronic device 1 according to the present embodiment, resistance R′ between a top surface of electronic component 40 and surface 22a of base portion 22 in heat sink 20 facing circuit board 10 is only R1=0.36 K/W.

Accordingly, electronic device 1 according to the present embodiment has superior heat-dissipation performance compared to electronic device 101 of the comparative example.

For example, in a case where power consumption of electronic component 40 is 10 W, temperature in electronic device 1 according to the present embodiment can be lowered by 2.286° C. compared to electronic device 101 of the comparative example.

For example, in a case where power consumption of electronic component 40 is 20 W, the temperature in electronic device 1 according to the present embodiment can be lowered by 4.572° C. compared to electronic device 101 of the comparative example.

For example, in a case where power consumption of electronic component 40 is 40 W, the temperature in electronic device 1 according to the present embodiment can be lowered by 9.144° C. compared to electronic device 101 of the comparative example.

In this manner, in electronic device 1 according to the present embodiment, heat emitted by electronic component 40 is transferred to base portion 22 of heat sink 20 via heat-dissipating component 50. The heat transferred is dispersed from base portion 22 and the plurality of fins 21. Accordingly, electronic device 1 according to the present embodiment has superior heat-dissipation performance compared to electronic device 101 of the comparative example.

Here, noise levels of electronic device 101 of the comparative example and noise levels of electronic device 1 according to the present embodiment will be described with reference to FIG. 2B.

FIG. 2B is a drawing that illustrates noise levels and frequencies of electronic component 40.

For example, in FIG. 2B, noise levels of an electronic device 1 in which standing walls 30 are not provided are indicated by the black circles and noise levels of electronic device 1 according to the present embodiment that includes standing walls 30 are indicated by the black squares.

Compared to the electronic device 1 in which standing walls 30 are not provided, in electronic device 1 according to the present embodiment that includes standing walls 30, for frequencies ranging from 0.5 GHz to 3 GHZ, noise levels are reduced by approximately 6 dB.

In this manner, in electronic device 1 according to the present embodiment, since heat sink 20 and standing walls 30 cover the surroundings of electronic component 40 so as to house electronic component 40, in electronic device 1 according to the present embodiment, heat sink 20 and standing walls 30 are more capable of blocking noise emitted by electronic component 40 when compared to an electronic device in which standing walls are not provided. Accordingly, noise becomes less likely to be emitted to the exterior of electronic device 1.

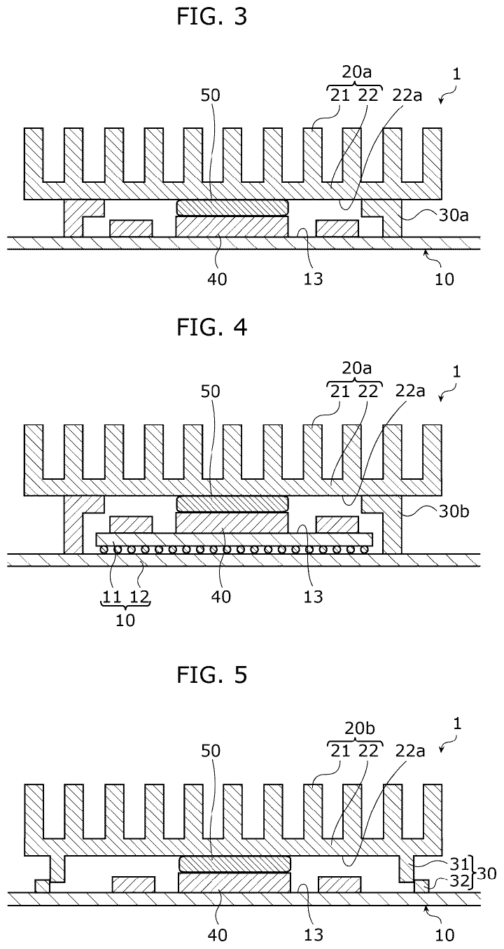

Next, as illustrated in FIG. 3, in electronic device 1 according to the present embodiment, standing walls 30a may be provided separate of heat sink 20a.

FIG. 3 is a cross-sectional view of an electronic device 1 in which heat sink 20a and standing walls 30a are provided as separate units.

Specifically, standing walls 30a are not provided as a single unit with heat sink 20a, and may be provided separately from heat sink 20a. One end of standing wall 30a facing circuit board 10 may be connected by solder to a second land of circuit board 10. In other words, standing walls 30a may be provided as a single unit with circuit board 10.

Standing walls 30a may extend toward heat sink 20a from a surface (surface 13) of circuit board 10 facing heat sink 20a. Since standing walls 30a surround electronic component 40 in a frame-like manner, heat sink 20a may be placed on other ends of standing walls 30a facing heat sink 20a to cover an opening defined by standing walls 30a. Heat sink 20a may be connected to and supported by standing walls 30a or circuit board 10 by fixing components, such as screws, bolts, or the like.

Even for such an electronic device 1, heat emitted by electronic component 40 is transferred to base portion 22 of heat sink 20a via heat-dissipating component 50. The heat transferred is dispersed from base portion 22 and the plurality of fins 21. Accordingly, electronic device 1 according to the present embodiment has superior heat-dissipation performance compared to electronic device 101 of the comparative example.

Furthermore, since heat sink 20a and standing walls 30a cover the surroundings of electronic component 40 so as to house electronic component 40, in electronic device 1 according to the present embodiment, noise that is emitted by electronic component 40 can be blocked.

Next, as illustrated in FIG. 4, circuit board 10 of electronic device 1 according to the present embodiment may include first substrate 11 on which electronic component 40 is mounted and second substrate 12 on which first substrate 11 is mounted. First substrate 11 and second substrate 12 may be configured in a manner similar to the above-mentioned circuit board 10.

FIG. 4 is a cross-sectional view of an electronic device 1 that includes first substrate 11 and second substrate 12.

First substrate 11 may be electrically connected to second substrate 12 by solder joining with second substrate 12.

Standing walls 30b surround electronic component 40 and first substrate 11 and are interposed between heat sink 20a and second substrate 12.

Standing walls 30b may be provided as a single unit with heat sink 20a. In this case, standing walls 30b extend toward second substrate 12 from base portion 22, and one end of standing wall 30b may be connected by solder to a second land of second substrate 12. Furthermore, standing walls 30b may be connected to second substrate 12 by fixing components, such as screws, bolts, or the like. Since standing walls 30b are interposed between heat sink 20a and second substrate 12, standing walls 30b and heat sink 20a may cover the surroundings of electronic component 40 and first substrate 11 so as to house electronic component 40 and first substrate 11.

Furthermore, standing walls 30b may be provided as units that are separate from heat sink 20a. In this case, one end of standing wall 30b facing second substrate 12 may be connected by solder to a second land of second substrate 12, and alternatively, standing walls 30b may be connected to second substrate 12 by fixing components, such as screws, bolts, or the like. In other words, standing walls 30b may be provided as a single unit with second substrate 12. Standing walls 30b may extend toward heat sink 20a from a surface of second substrate 12 facing heat sink 20a. Since standing walls 30b surround electronic component 40 in a frame-like manner, heat sink 20a may be placed on other ends of standing walls 30b facing heat sink 20a to cover an opening defined by standing walls 30b. Heat sink 20a may be connected to and supported by standing walls 30b or second substrate 12 by fixing components, such as screws, bolts, or the like.

Even in such an electronic device 1, heat emitted by electronic component 40 is transferred to base portion 22 of heat sink 20a via heat-dissipating component 50. The heat transferred is dispersed from base portion 22 and the plurality of fins 21. Accordingly, electronic device 1 according to the present embodiment has superior heat-dissipation performance compared to electronic device 101 of the comparative example.

Furthermore, since heat sink 20a and standing walls 30b cover the surroundings of electronic component 40 so as to house electronic component 40, in electronic device 1 according to the present embodiment, noise that is emitted by electronic component 40 can be blocked.

Next, as illustrated in FIG. 5, standing walls 30 in electronic device 1 according to the present embodiment may include first standing walls 31 that are provided as a single unit with heat sink 20b and second standing walls 32 that are provided as a single unit with circuit board 10.

FIG. 5 is a cross-sectional view of an electronic device 1 that includes first standing walls 31 and second standing walls 32.

First standing walls 31 may extend from surface 22a of heat sink 20b facing circuit board 10 toward second standing walls 32. In other words, first standing walls 31 may extend from surface 22a of base portion 22 in heat sink 20b facing circuit board 10 toward second standing walls 32. First standing walls 31 may be provided as a single unit with heat sink 20b.

Second standing walls 32 may extend from surface 13 of circuit board 10 facing heat sink 20b toward first standing walls 31. Second standing walls 32 may be provided as units that are separate from heat sink 20b. In this case, one end of second standing wall 32 facing circuit board 10 may be connected by solder to a second land of circuit board 10, and alternatively, standing walls 30 may be connected to circuit board 10 by fixing components, such as screws, bolts, or the like. In other words, second standing walls 32 may be provided as a single unit with circuit board 10.

Since second standing walls 32 surround electronic component 40 in a frame-like manner, heat sink 20b and first standing walls 31 may be placed on other ends of second standing walls 32 facing heat sink 20b to cover an opening defined by the other ends of second standing walls 32. Heat sink 20b may be connected to and supported by second standing walls 32 or circuit board 10 by fixing components, such as screws, bolts, or the like.

Furthermore, heat sink 20b may be electrically connected to a second land of circuit board 10, and alternatively, may be connected to second standing wall 32 that is connected to a second land.

Furthermore, distal ends of first standing walls 31 may be in contact with second standing walls 32, and alternatively, they need not be in contact with each other. It should be noted that from the standpoint of noise, so as to not allow gaps to be formed between first standing walls 31 and second standing walls 32, first standing walls 31 and second standing walls 32 may be provided so as to overlap with each other when viewed along surface 13 of circuit board 10, and furthermore, first standing walls 31 may be provided in contact with second standing walls 32. In other words, first standing walls 31 provided in a frame-like manner may be disposed on an outer peripheral side of second standing walls 32 provided in a frame-like manner, or may be disposed on an inner peripheral side of second standing walls 32.

### Functions and Effects

Next, the functions and effects of electronic device 1 according to the present embodiment will be described.

In the electronic device according to PTL 1, in a case where it is desired that heat transferred from an electronic component be dissipated by a lid, a separate heat sink can conceivably be provided on a surface of the lid. In this case, a heat-dissipating gel would be separately provided between the lid and the heat sink so as to be configured to allow heat transferred to the lid to escape to the heat sink. However, since a plurality of materials would be structurally interposed in the path through which heat emitted by the electronic component is transferred to the heat sink, thermal resistance will increase, thereby causing a problematic decrease in the heat-dissipation effect of the electronic component.

In view of this, as described earlier, electronic device 1 according to technique 1 of the present embodiment includes: circuit board 10 on which electronic component 40 that generates heat is mounted; heat sink 20, heat sink 20a, or heat sink 20b that covers electronic component 40 and is in contact with electronic component 40; and standing walls 30, standing walls 30a, or standing walls 30b that surround electronic component 40 and are interposed between heat sink 20, heat sink 20a, or heat sink 20b and circuit board 10.

Accordingly, since electronic component 40 and heat sink 20, heat sink 20a, or heat sink 20b are in contact with each other, heat emitted by electronic component 40 is more readily transferred to heat sink 20, heat sink 20a, or heat sink 20b. Accordingly, electronic device 1 according to the present embodiment has superior heat-dissipation performance compared to electronic device 101 of the comparative example.

Furthermore, since heat sink 20, heat sink 20a, or heat sink 20b and standing walls 30, standing walls 30a, or standing walls 30b cover the surroundings of electronic component 40 so as to house electronic component 40, heat sink 20, heat sink 20a, or heat sink 20b and standing walls 30, standing walls 30a, or standing walls 30b can block noise that is emitted by electronic component 40.

Consequently, such an electronic device 1 can suppress radiated noise from electronic component 40, while also improving the heat-dissipation performance of electronic component 40.

Furthermore, electronic device 1 according to technique 2 of the present embodiment is electronic device 1 according to technique 1, further including heat-dissipating component 50 interposed between electronic component 40 and heat sink 20, heat sink 20a, or heat sink 20b.

Accordingly, by disposing heat-dissipating component 50 between electronic component 40 and heat sink 20, heat sink 20a, or heat sink 20b, heat-dissipating component 50 can efficiently transfer the heat emitted by electronic component 40 to heat sink 20, heat sink 20a, or heat sink 20b. Consequently, the heat-dissipation performance of electronic component 40 can be improved.

Furthermore, electronic device 1 according to technique 3 of the present embodiment is electronic device 1 according to technique 1 or 2. In this case, standing walls 30, standing walls 30a, or standing walls 30b extend toward circuit board 10 from surface 22a of heat sink 20, heat sink 20a, or heat sink 20b facing circuit board 10, and are provided as a single unit with heat sink 20, heat sink 20a, or heat sink 20b.

Accordingly, since standing walls 30, standing walls 30a, or standing walls 30b and heat sink 20, heat sink 20a, or heat sink 20b are provided as a single unit, the number of components in electronic device 1 can be prevented from increasing. Furthermore, since a component in which standing walls 30, standing walls 30a, or standing walls 30b and heat sink 20, heat sink 20a, or heat sink 20b are provided as a single unit can be connected to circuit board 10, the number of man-hours to assemble standing walls 30, standing walls 30a, or standing walls 30b and heat sink 20, heat sink 20a, or heat sink 20b with circuit board 10 can be prevented from increasing. As a result, the manufacturing cost of electronic device 1 can be prevented from increasing.

Furthermore, electronic device 1 according to technique 4 of the present embodiment is electronic device 1 according to technique 1 or 2. In this case, standing walls 30, standing walls 30a, or standing walls 30b extend toward heat sink 20a or heat sink 20b from a surface of circuit board 10 facing heat sink 20a or heat sink 20b, and are provided as a single unit with circuit board 10.

Accordingly, since circuit board 10 and standing walls 30, standing walls 30a, or standing walls 30b are provided as a single unit, the number of components in electronic device 1 can be prevented from increasing. Furthermore, since a component in which circuit board 10 and standing walls 30, standing walls 30a, or standing walls 30b are provided as a single unit can simply be connected to heat sink 20a or heat sink 20b, the number of man-hours to assemble circuit board 10 and standing walls 30, standing walls 30a, or standing walls 30b with heat sink 20a or heat sink 20b can be prevented from increasing. As a result, the manufacturing cost of electronic device 1 can be prevented from increasing.

Furthermore, electronic device 1 according to technique 5 of the present embodiment is electronic device 1 according to any one of techniques 1 to 4. In this case, circuit board 10 includes first substrate 11 on which electronic component 40 is mounted and second substrate 12 on which first substrate 11 is mounted, and standing walls 30b surround electronic component 40 and first substrate 11 and are interposed between heat sink 20a and second substrate 12.

Accordingly, since heat sink 20a and standing walls 30b cover the surroundings of electronic component 40 and first substrate 11 so as to house electronic component 40 and first substrate 11, heat sink 20a and standing walls 30b are not only capable of blocking noise emitted by electronic component 40, but are also capable of blocking noise emitted by first substrate 11.

Furthermore, electronic device 1 according to technique 6 of the present embodiment is electronic device 1 according to any one of techniques 1 to 5. In this case, standing walls 30 include first standing walls 31 that are provided as a single unit with heat sink 20b and second standing walls 32 that are provided as a single unit with circuit board 10, first standing walls 31 extend toward second standing walls 32 from surface 22a of heat sink 20b facing circuit board 10, and second standing walls 32 extend toward first standing walls 31 from a surface (surface 13) of circuit board 10 facing heat sink 20b.

Accordingly, since heat sink 20b, first standing walls 31, and second standing walls 32 cover the surroundings of electronic component 40 so as to house electronic component 40, heat sink 20b, first standing walls 31, and second standing walls 32 are capable of blocking noise emitted by electronic component 40.

Furthermore, electronic device 1 according to technique 7 of the present embodiment is electronic device 1 according to any one of techniques 1 to 6. In this case, electronic component 40 is at least one of a system on a chip (SoC), a power supply integrated circuit (IC), or a memory element.

Accordingly, even when electronic component 40 generates heat, the heat can be dissipated, and noise emitted by electronic component 40 can be blocked.

### Other Variations, Etc.

While the electronic device according to the present disclosure has been described based on the above-described embodiment, the present disclosure is not limited to this embodiment. The present disclosure may include forms obtained by various modifications to the foregoing embodiment that can be conceived by those skilled in the art, for as long as they do not depart from the essence of the present disclosure.

It should be noted that the present disclosure includes forms obtained by making various modifications to the above-described embodiment that can be conceived by those skilled in the art, as well as forms realized by arbitrarily combining elements and functions in different embodiments without materially departing from the essence of the present disclosure.

While an embodiment has been described herein above, it is to be appreciated that various changes in form and detail may be made without departing from the spirit and scope of the present disclosure as presently or hereafter claimed.

### Further Information about Technical Background to this Application

The disclosure of the following patent application including specification, drawings, and claims is incorporated herein by reference in its entirety: Japanese Patent Application No. 2024-052923 filed on Mar. 28, 2024.

### INDUSTRIAL APPLICABILITY

The present disclosure can, for example, be applied to devices for in-vehicle use provided in vehicles and information processing devices, such as computers and the like.

1. An electronic device comprising:
a circuit board on which an electronic component that generates heat is mounted;
a heat sink that covers the electronic component and is in contact with the electronic component; and
a standing wall that surrounds the electronic component and is interposed between the heat sink and the circuit board.

2. The electronic device according to claim 1, further comprising:
a heat-dissipating component interposed between the electronic component and the heat sink.

3. The electronic device according to claim 1, wherein
the standing wall extends toward the circuit board from a surface of the heat sink facing the circuit board, and is provided as a single unit with the heat sink.

4. The electronic device according to claim 1, wherein
the standing wall extends toward the heat sink from a surface of the circuit board facing the heat sink, and is provided as a single unit with the circuit board.

5. The electronic device according to claim 1, wherein
the circuit board includes a first substrate on which the electronic component is mounted and a second substrate on which the first substrate is mounted, and
the standing wall surrounds the electronic component and the first substrate and is interposed between the heat sink and the second substrate.

6. The electronic device according to claim 1, wherein
the standing wall includes a first standing wall that is provided as a single unit with the heat sink and a second standing wall that is provided as a single unit with the circuit board,
the first standing wall extends toward the second standing wall from a surface of the heat sink facing the circuit board, and
the second standing wall extends toward the first standing wall from a surface of the circuit board facing the heat sink.

7. The electronic device according to claim 1, wherein
the electronic component is at least one of a system on a chip (SoC), a power supply integrated circuit (IC), or a memory element.
